(19) United States
(12) Patent Application Publication
(10) Pub. No.: US 2008/0291715 A1
(43) Pub. Date: Nov. 27, 2008

(54) NONVOLATILE MEMORY DEVICE USING VARIABLE RESISTIVE MATERIALS

(75) Inventors: Mu-Hui PARK, Seocho-gu (KR); Kwang-Jin LEE, Hwaseong-si (KR); Du-Eung KIM, Yongin-si (KR); Hye-Jin KIM, Gangnam-gu (KR); Woo-Yeong CHO, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/116,295

(22) Filed: May 7, 2008

(30) Foreign Application Priority Data
May 23, 2007 (KR) 10-2007-0050375

(51) Int. Cl. G11C 11/00; G11C 7/00

(52) U.S. Cl. 365/148; 365/189.15; 365/203

(57) ABSTRACT

A nonvolatile memory device includes a nonvolatile memory cell, a read circuit and a control bias generating circuit. The nonvolatile memory cell has a resistance level that changes depending on stored data. The read circuit reads the resistance level of the nonvolatile memory cell by receiving a control bias and supplying the nonvolatile memory cell a read bias based on the control bias. The control bias generating circuit receives an input bias, generates the control bias based on the input bias and supplies the control bias to the read circuit. A slope of the control bias to the input bias is less than 1.

### CROSS REFERENCE TO RELATED APPLICATION

A claim of priority is made to Korean Patent Application No. 10-2007-0050375, filed on May 23, 2007, the subject matter of which is hereby incorporated by reference.

### BACKGROUND OF THE INVENTION

1. Field of the Invention

The present invention relates to a nonvolatile memory device. More particularly, the present invention relates to a nonvolatile memory device including a nonvolatile memory cell having resistance level changes depending on stored data.

2. Description of the Related Art

Nonvolatile memory devices using resistance materials include RRAM (Resistive Random Access Memory), PRAM (Phase Change Random Access Memory), and MRAM (Magnetic Random Access Memory). DRAM (Dynamic Random Access Memory) and flash memory devices store data using charges. Nonvolatile memory devices using resistance materials store data using the resistance change of variable resistive elements (e.g., RRAM), phase change of phase change materials such as chalcogenide alloy (e.g., PRAM), and resistance change of MTJ (Magnetic Tunnel Junction) thin films according to the magnetization state of a ferromagnetic substance.

Using phase change memory cells as an example, phase change material changes into a crystal state or an amorphous state by cooling after heating. Since the phase change material in the crystal state has a low resistance and the phase change material in the amorphous status has a high resistance, the crystal state is defined as set data (0), and the amorphous status is defined as reset data (1).

A read circuit to read data stored in phase change memory cells can include a sensing node coupled with a phase change memory cell, a read bias supplier to apply a read bias to the sensing node in response to control bias in order to read a resistance level of the phase change memory cell, a sense amplifier to compare the sensing node level to the reference level and output the level difference. The level of the control bias must be properly adjusted, since the control bias is used to determine the amount of current that flows through the phase change memory cell and the level of the sensing node.

### SUMMARY OF THE INVENTION

According to one aspect of the invention, a nonvolatile memory device includes a nonvolatile memory cell having a resistance level that changes depending on stored data; a read circuit that reads the resistance level of the nonvolatile memory cell by receiving a control bias and supplying the nonvolatile memory cell a read bias based on the control bias; and a control bias generating circuit that receives an input bias, generates the control bias based on the input bias and supplies the control bias to the read circuit. A slope of the control bias to the input bias is less than 1. The control bias generating circuit may control the slope of the control bias to the input bias based on a slope control signal. The slope control signal may be one of a temperature signal, an MRS (Mode Register Set) signal, or a fuse box signal.

According to another aspect of the invention, a nonvolatile memory device includes a nonvolatile memory cell having a resistance level that changes depending on stored data; a read circuit that reads the resistance level of the nonvolatile memory cell by receiving a control bias and supplying the nonvolatile memory cell a read bias based on the control bias; and a control bias generating circuit that receives an input bias, generates the control bias based on the input bias, supplies the control bias to the read circuit, and controls a slope of the control bias to the input bias depending on a slope control signal.

According to still another aspect of the invention, a nonvolatile memory device includes a nonvolatile memory cell which has a resistance level that is changeable depending on stored data; a read circuit that reads the resistance level of the nonvolatile memory cell by receiving a control bias and supplying the nonvolatile memory cell a read bias based on the control bias; and a control bias generating circuit that receives an input bias, generates the control bias based on the input bias and supplies the control bias to the read circuit. A slope of the control bias to the input bias is different in multiple regions depending on a level of the input bias.

According to still another aspect of the invention, a nonvolatile memory device includes a first bias generator that receives an input bias and generates a first bias having a level higher than the input bias; a second bias generator that receives the input bias and generates a second bias having a level lower than the input bias; and a third bias generator that generates a third bias using the first bias and the second bias. A slope of the third bias to the input bias is less than 1.

### BRIEF DESCRIPTION OF THE DRAWINGS

The embodiments of the present invention will be described with reference to the attached drawings, in which:

FIG. 1 is a block diagram illustrating a nonvolatile memory device, according to exemplary embodiments of the present invention;

FIG. 2 is a circuit diagram illustrating the blocks shown in FIG. 1, according to exemplary embodiments of the present invention;

FIG. 3 is a graph illustrating a relationship between input bias and control bias of an operation in a control bias generating circuit shown in FIG. 1, according to an exemplary embodiment of the present invention;

FIG. 4 is a graph illustrating a relationship between input bias and resistance when the relationship between input bias and control bias is the same as that of FIG. 3, according to an exemplary embodiment of the present invention;

FIG. 5 is a graph illustrating a relationship between input bias and resistance distribution when the relationship between input bias and control bias is the same as that of FIG. 3, according to an exemplary embodiment of the present invention;

FIGS. 6 through 8 are graphs illustrating relationships between input bias and control bias in various operations of the control bias generating circuit, according to exemplary embodiments of the present invention;

FIG. 9 is a block diagram illustrating a control bias generating circuit shown in FIG. 1, according to an exemplary embodiment of the present invention;

FIG. 10 is a circuit diagram illustrating a control bias generating circuit shown in FIG. 9, according to an exemplary embodiment of the present invention;

FIG. 11 is a circuit diagram illustrating control signaling of a control bias generating circuit, according to an exemplary embodiment of the present invention;

FIGS. 12A, and 12B are graphs illustrating operation of a control bias generating circuit shown in FIG. 11, according to an embodiment of the present invention;

FIG. 13 is a circuit diagram illustrating control signaling of a control bias generating circuit, according to an exemplary embodiment of the present invention;

FIGS. 14A, and 14B are graphs illustrating operation of a control bias generating circuit shown in FIG. 13;

FIG. 15 is a block diagram illustrating detecting and amplification units of a control bias generating circuit, according to another exemplary embodiment of the present invention;

FIG. 16 is a graph illustrating operation of the block diagram shown in FIG. 15, according to an exemplary embodiment of the present invention;

FIG. 17 is a block diagram illustrating detecting, amplification and compensation units of a control bias generating circuit, according to another exemplary embodiment of the present invention; and

FIG. 18 is a set of graphs illustrating operation of the block diagram shown in FIG. 17, according to an exemplary embodiment of the present invention.

### DETAILED DESCRIPTION OF THE EMBODIMENTS

The present invention will now be described more fully with reference to the accompanying drawings, in which exemplary embodiments of the invention are shown. The invention may, however, be embodied in various different forms, and should not be construed as being limited only to the illustrated embodiments. Rather, these embodiments are provided as examples, to convey the concept of the invention to one skilled in the art. Accordingly, known processes, elements, and techniques are not described with respect to some of the embodiments of the present invention. Throughout the drawings and written description, like reference numerals will be used to refer to like or similar elements.

In the following description, it will be understood that when an element is referred to as being “connected to” or “coupled to” another element, it can be directly connected to or coupled to the other element or intervening elements may also be present. In contrast, when an element is referred to as being “directly connected to” or “directly coupled to” another element, there are no intervening elements present. As used herein, the term “and/or” includes any and all combinations of one or more of the associated listed items.

Although terms such as “the first” and “the second” are used to describe various elements, components, and/or sections, such elements, components, and/or sections are not limited by this terminology. Such terms are used to distinguish one element, component, and/or section from another element, component, and/or section. For example, a first element, component, or section could be termed a second element, component, or section without departing from the scope of the present invention.

As used herein, terms are used to explain exemplary embodiments. It will be understood that these terms are not limiting. Unless specifically stated, a word in singular form also represents plural form. The terms “comprise” and/or “comprising” used in the specification may include elements, steps, operations and/or devices specifically mentioned in the specification, as well as other elements, steps, and operations, and/or devices.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, although exemplary embodiments of the present invention will be described as using a phase change random access memory (PRAM), the embodiments of the present invention can be applied to all kinds of nonvolatile memory devices using a resistive element, such as resistive RAM (RRAM) and ferroelectric RAM (FRAM).

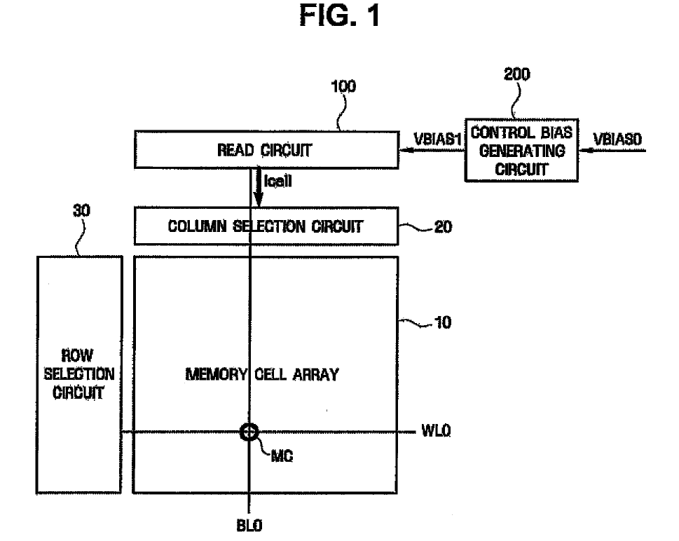

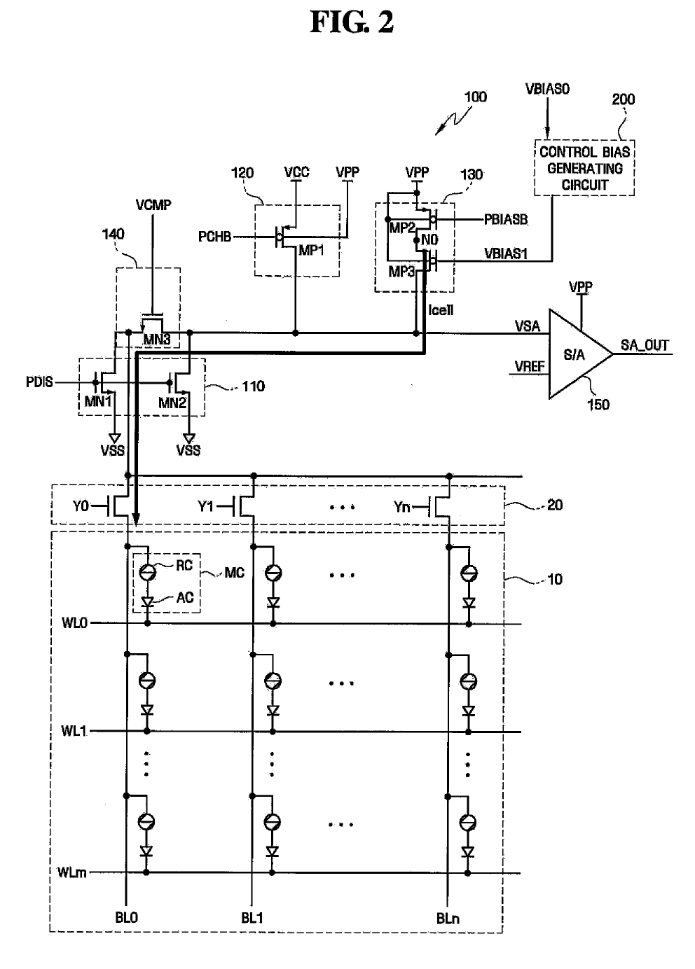

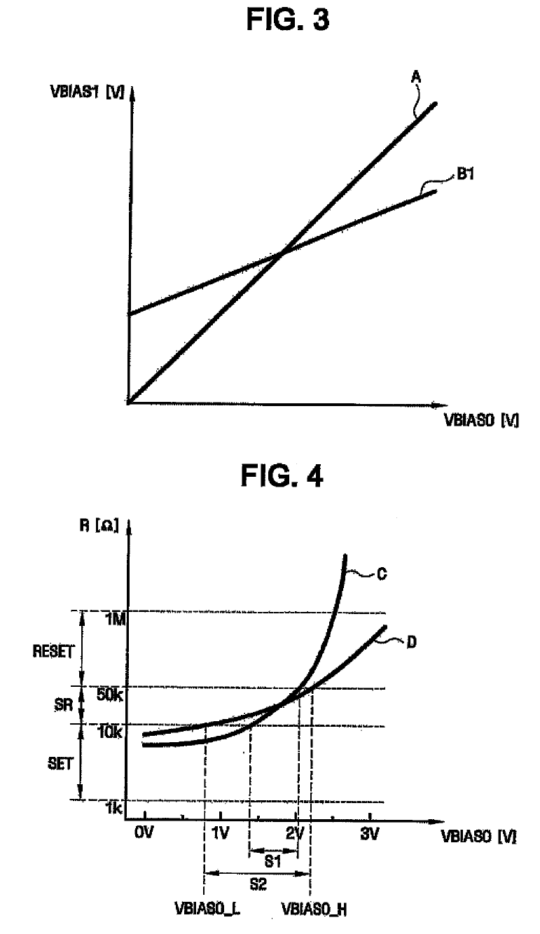

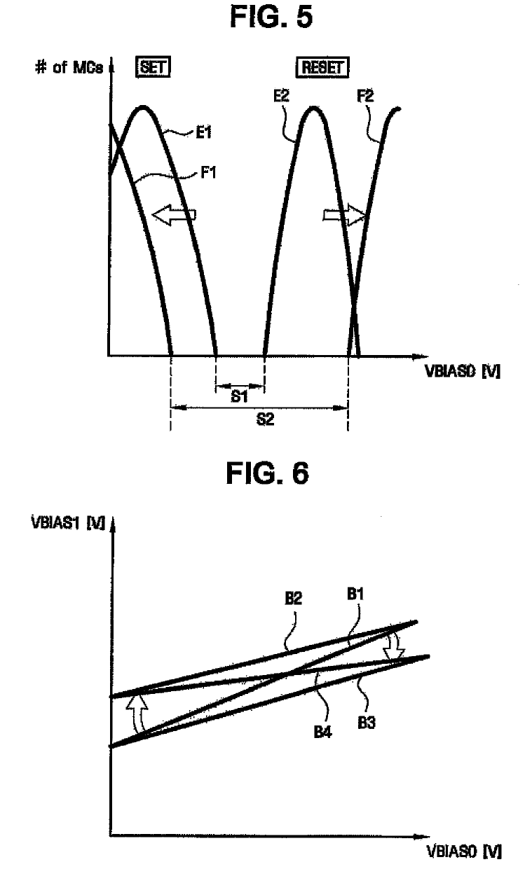

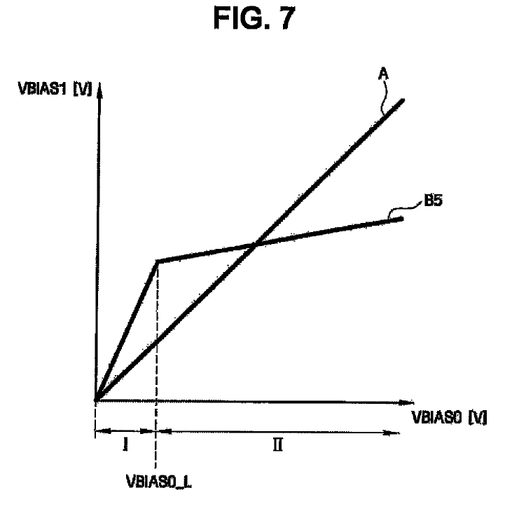

FIG. 1 is a block diagram illustrating a nonvolatile memory device, according to exemplary embodiments of the present invention. FIG. 2 is a circuit diagram illustrating blocks shown in FIG. 1, according to exemplary embodiments of the present invention, although a row selection circuit is not illustrated in FIG. 2 for the sake of explanatory convenience. FIG. 3 is a graph illustrating a relationship between input bias and control bias, in order to explain an operation in a control bias generating circuit shown in FIG. 1. FIG. 4 is a graph illustrating a relationship between the input bias and resistance when the relationship between the input bias and the control bias is the same as that shown in FIG. 3. FIG. 5 is a graph illustrating a relationship between the input bias and a resistance distribution when a relationship between the input bias and the control bias is the same as that shown in FIG. 3.

Referring to FIGS. 1 and 2, a nonvolatile memory device, according to exemplary embodiments of the present invention, includes a memory cell array 10, a column selection circuit 20, a row selection circuit 30, a read circuit 100, and a control bias generating circuit 200.

The memory cell array 10 includes multiple nonvolatile memory cells MC arranged in a matrix shape. Each nonvolatile memory cell MC is coupled between a word line WL0-WLm and a bit line BL0-BLn. Also, each nonvolatile memory cell MC may include a variable resistive element RC that includes a phase change material having two different resistances according to a crystal state and an amorphous status, and an access element AC that controls current flow in the variable resistive element RC. The access element AC may be a diode or a transistor coupled to the variable resistive element RC in series. A diode is illustrated as the variable resistive element RC in FIG. 2. Also, the phase change material may use various materials, such as two atomic compounds, such as GaSb, InSb, InSe, Sb₂Te₃ or GeTe, three atomic compounds, such as GeSbTe, GaSeTe, InSbTe, SnSb₂Te₄ or InSbGe, or four atomic compounds, such as AgInSbTe, (GeSn)SbTe, GeSb(SeTe) or Te₈₁Ge₁₅Sb₂S₂. In an embodiment, GeSbTe, consisting of germanium (Ge), antimony (Sb) and tellurium (Te), is used in particular.

The column selection circuit 20 selects a subset of the word lines (e.g., WL0) from among the multiple word lines WL0-WLm, and the row selection circuit 30 selects a subset of bit lines (e.g., BL0) from among the multiple bit lines BL0-BLn.

The read circuit 100 reads data stored in the nonvolatile memory cell MC selected in the memory cell array 10. More specifically, the read circuit 100 reads a resistance level of the nonvolatile memory cell MC by supplying the nonvolatile memory cell MC selected by control bias VBIAS1 with read bias Icell.

The read circuit 100, as illustrated in FIG. 2, includes a discharge circuit 110, a precharge circuit 120, a read bias generating circuit 130, a clamping circuit 140, and a sense amplifier circuit 150.

The discharge circuit 110 discharges the bit line (e.g., BL0) coupled with the nonvolatile memory cell MC selected before the read operation and/or a sensing node VSA to a predetermined voltage, for example, ground voltage VSS. The discharge circuit 110 can include a NMOS transistor MN1, which is coupled between the bit line BL0 and the ground voltage VSS and receives a discharge signal PDIS through a gate, and a NMOS transistor MN2, which is coupled between the sensing node VSA and the ground voltage VSS and receives the discharge signal PDIS through a gate.

The precharge circuit 120 precharges the sensing node VSA to a predetermined level, for example, a source voltage VCC during the precharge period in a data read operation. The precharge circuit 120 can be a PMOS transistor MP1, which is coupled between the source voltage VCC and the sensing node VSA, and receives a precharge signal PCHB through the gate.

The read bias generating circuit 130 responds to the control bias VBIAS1 and supplies the sensing node VSA with the read bias Icell to read the resistance level of the selected nonvolatile memory cell MC. When the data stored in the nonvolatile memory cell MC is set data, the amount of current which flows through the nonvolatile memory cell MC is large since the resistance of the phase change material is small. When the data stored in the nonvolatile memory cell MC is reset data, the amount of the current that flows through the nonvolatile memory cell is small since the resistance of the phase change material is large.

The amount of the read bias Icell supplied by the read bias generating circuit 130 can be an amount that compensates for the current flowing in a reset state. By doing this, the level of the sensing node VSA can be maintained at a certain level or slightly increased when the reset data is stored. When the set data is stored, the level of the sensing node VSA is decreased. Therefore, the set data can be easily distinguished from the reset data since the difference between the level of the sensing node VSA of the reset data and the level of the sensing node VSA of the set data can be large. As a result, the sensing margin can be increased. The read bias generating circuit 130 includes a PMOS transistor MP2, which is coupled between operation voltage VPP and a node N0 and receives a selection signal PBIASB through a gate, and a PMOS transistor MP3 which is coupled in between the node N0 and the sensing node VSA and receives the control bias VBIAS through the gate. Each of the substrate regions where the PMOS transistors MP2 and MP3 are formed can be coupled to the operation voltage VPP.

The clamping circuit 140 clamps the level of the bit line BL0 to a certain bias level, for example, within a proper range to read. More specifically, the clamping circuit 140 clamps the level of the bit line BL0 to a level below the critical voltage Vth of the phase change materials. This is because the phase of the phase change material of selected nonvolatile memory cell MC can change if the clamping level is above the critical voltage Vth. The clamping circuit 140 can be a NMOS transistor MN3, which is coupled between the bit line BL0 and the sensing node VSA and receives a clamping signal VCMP through a gate. The clamping control signal VCMP may be a voltage regulator signal, for example, but is not limited thereto.

The sense amplifier circuit 150 outputs the comparison output SA_OUT by comparing the level of the sensing node VSA and reference level VREF. For example, when the sensing the level of the node VSA is higher than the reference level VREF, a high level of the comparison output SA_OUT is generated. In contrast, when the sensing the level of the node VSA is lower than the reference level VREF, a low level of the comparison output SA_OUT is generated. When the comparison output SA_OUT is at the high level, the nonvolatile memory cell MC stores reset data, and when the comparison output SA_OUT is at the low level, the nonvolatile memory cell MC stores set data. The sense amplifier circuit 150 may be a current sense amplifier, for example, that senses a current change that flows through the bit line BL0 of the selected nonvolatile memory cell MC against the reference current. Alternatively, sense amplifier circuit 150 may be a voltage sense amplifier, for example, that senses a voltage change against the reference voltage. FIG. 2, in particular, depicts the sense amplifier circuit 150 as a voltage sense amplifier, as an illustrative example.

In the nonvolatile memory devices, according to exemplary embodiments of the present invention, the control bias VBIAS1 provided to the read circuit 100 (specifically, the read bias generating circuit 130) is supplied by the control bias generating circuit 200. The control bias generating circuit 200 generates the control bias VBIAS1 by receiving input bias VBIAS0, and the ratio of the control bias VBIAS1 to the input bias VBIAS0 is less than 1. The ratio of the control bias VBIAS1 to the input bias VBIAS0 means the value which can be obtained by dividing the amount of the control bias VBIAS1 increase by the amount of the input bias VBIAS0 increase. Therefore, in the nonvolatile memory devices according to the exemplary embodiments of the present invention, the amount of the control bias VBIAS1 increase is smaller than the amount of the input bias VBIAS0 increase.

The operation of the control bias generating circuit 200 is explained with reference to FIGS. 3 through 5.

Referring to FIG. 3, the x-axis represents the input bias VBIAS0 and the y-axis represents the control bias VBIAS1. Line A serves as a reference line provided for the sake of explanation. Line A has a slope of 1, meaning that the ratio (or slope) of the control bias VBIAS1 to the input bias VBIAS0 is 1. Line A thus indicates an operation in which the control bias generating circuit 200 receives the input bias VBIAS0 as input and generates the control bias VBIAS1 as output without change. Line B1 of FIG. 3 has a slope of less than 1. Line B1 thus indicates an operation in which the control bias generating circuit 200 receives the input bias VBIAS0, and outputs the control bias VBIAS1, such that the ratio of the control bias VBIAS1 to the input bias VBIAS0 is less than 1.

Referring to FIG. 4, the x-axis represents the input bias VBIAS0 and y-axis represents a resistance R. The y-axis has a log scale to show the resistance distribution.

Figure index C indicates a resistance value of the point where the level of the sensing node VSA is the same as the reference level VREF when the control bias generating circuit 200 receives the input bias VBIAS0 and supplies the control bias VBIAS1, as shown by line A of FIG. 3, to the read bias generating circuit 130. Figure index D indicates the resistance value of the point where the level of the sensing node VSA is the same as the reference level VREF when the control bias generating circuit 200 receives the input bias VBIAS0 and supplies the control bias VBIAS1, as shown by line B of FIG. 3, to the read bias generating circuit 130.

The input bias VBIAS0 can be set such that the point where the level of the sensing node VSA is the same as the reference level VREF is located between the maximum resistance value of the set data SET and the minimum resistance value of the reset data RESET. That is, the input bias VBIAS0 can be set to have a range between level VBIAS_L corresponding to the maximum resistance value of the set data SET and level VBIAS_H corresponding to the minimum resistance value of the reset data RESET. For example, since the resistance range of the reset data RESET is from about 50 kΩ to about 1 MΩ and the resistance range of the set data SET is from about 1 kΩ to about 10 kΩ, the level of the input bias VBIAS0 can be set between about 10 kΩ and about 50 kΩ. Hereinafter, a sensing range SR is defined as the range between the maximum resistance value of the set data SET and the minimum resistance value of the reset data RESET.

Reference label C is a curve showing setting range S1 of the input bias VBIAS0 (i.e., the sensing margin of the input bias VBIAS0) from about 1.4 V to about 2.0 V. Reference label D is a curve showing a setting range S2 (i.e., the sensing margin of the input bias VBIAS0) from about 0.8 V to about 2.3 V. This indicates that the setting range of the input bias VBIAS0 indicated by curve D is larger than that indicated by curve C. This is because the range of the input bias VBIAS0 corresponding to the sensing range SR becomes wider since the slope of the control bias VBIAS1 to the input bias VBIAS0 is less than 1.

Referring to FIG. 5, the x-axis represents the input bias VBIAS0 and the y-axis represents the number of the memory cells.

Reference labels E1 and E2 are curves indicating the resistance distribution of the set data SET and the resistance distribution of the reset data RESET, respectively, when the control bias generating circuit 200 receives the input bias VBIAS0 and supplies the control bias VBIAS1 to the read bias generating circuit 130, as shown by line A of FIG. 3. Reference labels F1 and F2 are curves indicating the resistance distribution of the set data SET and the resistance distribution of the reset data RESET, respectively, when the control bias generating circuit 200 receives the input bias VBIAS0 and supplies the read bias generating circuit 130 with the control bias VBIAS1, as shown by line B of FIG. 3. This indicates that the sensing margin S2 of the input bias VBIAS0 depicted by F1 and F2 is larger than the sensing margin S1 of the input bias VBIAS0 depicted by E1 and E2.

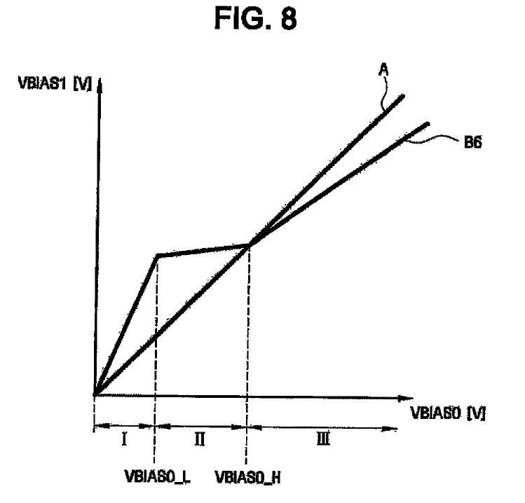

FIGS. 6 through 8 are graphs illustrating the relationship between input bias and control bias to show various operations of the control bias generating circuit. FIG. 6 is a graph illustrating that the slope of the control bias to the input bias may vary. FIGS. 7 and 8 are graphs illustrating multiple regions of input bias level where each of the regions has a unique slope of the control bias to the input bias.

Referring to FIG. 6, according to an exemplary embodiment of the present invention, the slope of the control bias VBIAS1 to the input bias VBIAS0 can vary. That is, the sensing margin can be reduced, for example, due to fabrication process changes or operating environment changes (e.g., temperature changes) of the nonvolatile memory device. When such changes occur, the sensing margin can be secured by controlling the slope of the control bias VBIAS1 to the input bias VBIAS0.

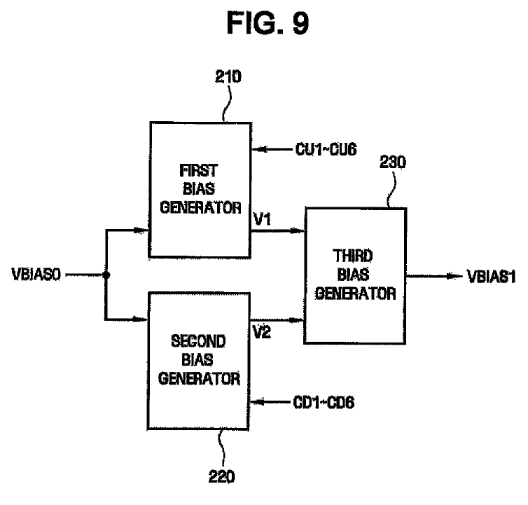

FIG. 6 is a graph illustrating cases in which the slope of the control bias VBIAS1 to input bias VBIAS0 can be reduced. For example, the slope can be reduced by moving the line B1 to any of lines B2, B3 or B4. Exemplary block and circuit diagrams of the control bias generating circuit 200 and corresponding graphs for adjusting the slope of the control bias VBIAS1 to the input bias VBIAS0, as shown in FIG. 6, are described below, with reference to FIGS. 9 through 14B.

FIG. 7 is a graph illustrating cases in which the slope of the control bias VBIAS1 to the input bias VBIAS0 changes in two different regions, regions I and II, each of the regions corresponding to a certain range of the input bias VBIAS0 level. In FIG. 7, the slope of the control bias VBIAS1 to the input bias VBIAS0 in the second region II is less than the slope of the control bias VBIAS1 to the input bias VBIAS0 in the first region I. More specially, FIG. 7 shows the slope of the control bias VBIAS1 to the input bias VBIAS0 in the second region II being less than 1.

In the first region I, the input bias VBIAS0 may be less than a first level VBIAS0_L, and in the second region II the input bias VBIAS0 may be greater than the first level VBIAS0_L. The first level VBIAS0_L may be equal to or greater than the bias level corresponding to the maximum resistance level of the set data. For example, the first level VBIAS0_L can be about 0.8 V (refer to FIG. 4). Although the first level VBIAS0_L is set using the input bias VBIAS0 as the reference level, the first level VBIAS0_L may likewise be set using the control bias VBIAS1 as the reference level.

Since the slope of the control bias VBIAS1 to the input bias VBIAS0 in the second region II is less than 1, the range of the input bias VBIAS0 corresponding to the sensing range SR (refer to FIG. 4) is wide.

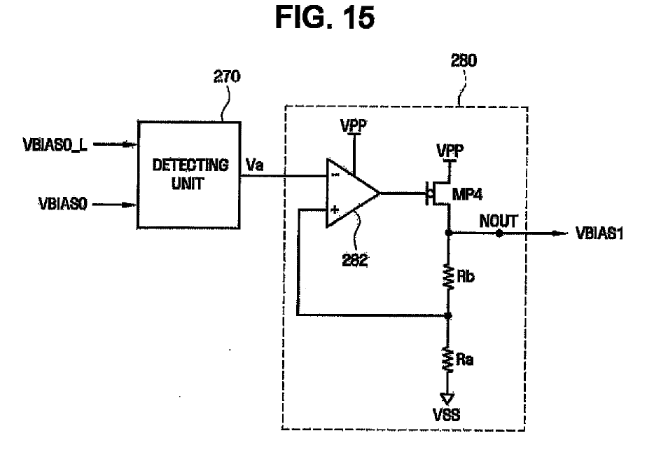

An exemplary circuit diagram showing the control bias generating circuit 200 for generating different slopes of the control bias VBIAS1 to the input bias VBIAS0 in multiple regions as shown in FIG. 7 is described below with reference to FIG. 15.

FIG. 8 is a graph illustrating cases in which the slope of the control bias VBIAS1 to the input bias VBIAS0 changes in three different regions, regions I, II and III, each of the regions corresponding to a certain range of the input bias VBIAS0 level. In FIG. 8, the slope of the control bias VBIAS1 to the input bias VBIAS0 in the second region II is less than the slopes of the control bias VBIAS1 to the input bias VBIAS0 in the first region I and the third region III. Specially, the slope of the control bias VBIAS1 to the input bias VBIAS0 in the second region II can be less than 1.

In the depicted example, the input bias VBIAS0 can be smaller than the first level VBIAS0_L in the first region I. Also, in the second region II, the input bias VBIAS0 can be greater than the first level VBIAS0_L and less than the second level VBIAS0_H, and in the third region III, the input bias VBIAS0 can be greater than the second level VBIAS0_H. The first level VBIAS0_L may be equal to or greater than the bias level corresponding to the maximum resistance level of the set data. For example, the first level VBIAS0_L may be about 0.8 V (refer to FIG. 4). The second level VBIAS0_H may be equal to or less than the bias level corresponding to the minimum resistance level of the reset data. For example, the first level VBIAS0_L can be about 0.8 V, and the second level VBIAS0_H can be about 2.3 V (refer to FIG. 4). Although the first level VBIAS0_L and the second level VBIAS0_H are set using the input bias VBIAS0 as the reference level, the control bias VBIAS1 can likewise be used as the reference level to set the first level VBIAS0_L and the second level VBIAS0_H.

Since the slope of the control bias VBIAS1 to the input bias VBIAS0 in the second region II is less than 1, the range of the input bias VBIAS0 corresponding to the sensing range SR (refer to FIG. 4) is wide.

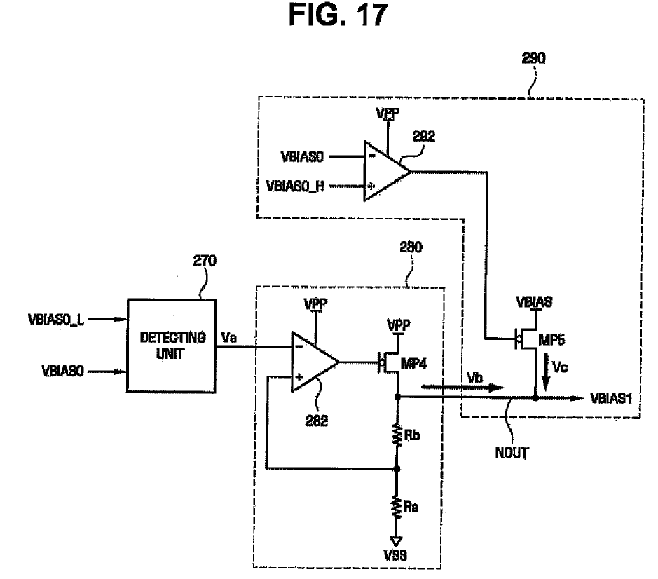

An exemplary circuit diagram showing the control bias generating circuit 200 for generating different slopes of the control bias VBIAS1 to the input bias VBIAS0 in multiple regions as shown in FIG. 8 is described below with reference to FIG. 17.

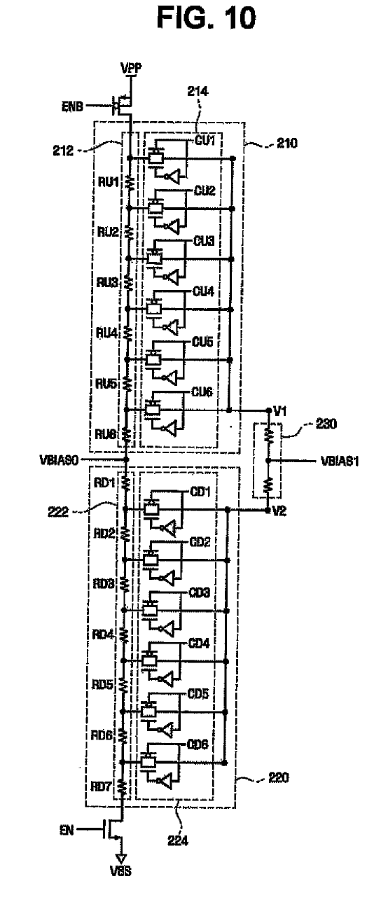

FIG. 9 is a block diagram and FIG. 10 is a circuit diagram illustrating a control bias generating circuit shown and described with respect to FIGS. 1, 3 and 6, according to exemplary embodiments of the present invention, although the present invention is not limited to these implementations.

Referring to FIGS. 9 and 10, the control bias generating circuit includes a first bias generator 210, a second bias generator 220, and a third bias generator 230. The control bias generating circuit can be enabled, for example, by receiving an enable signal EB and an inverse enable signal ENB as input.

The first bias generator 210 generates first bias V1, which has a higher level than that of the input bias VBIAS0. Also, the first bias generator 210 can change the first bias V1 level based on received slope control signals CU1-CU6. The first bias generator 210 includes a first resistance string 212, which includes multiple resistors RU1-RU6 coupled in series between an operation voltage node VPP and a node to which the input bias VBIAS0 is applied. The first bias generator 210 also includes a first selection circuit 214, which receives the slope control signals CU1-CU6 as input and selectively outputs one node voltage as the first bias V1 from among the node voltages on the first resistance string 212.

The second bias generator 220 generates a second bias V2, which has a lower level than that of the input bias VBIAS0. Also, the second bias generator 220 can change the second bias V2 level based on received slope control signals CD1-CD6. The second bias generator 220 includes a second resistance string 222, which includes multiple resistors RD1-RD7 coupled in series between a ground voltage node VSS and a node to which the input bias VBIAS0 is applied. The second bias generator 220 also includes a second selection circuit 224, which receives the slope control signals CD1-CD6 as input and selectively outputs one node voltage as the second bias V2 from among the node voltages in the second resistance string 222.

The third bias generator 230 generates the control bias VBIAS1 using the first bias V1 and the second bias V2. The third bias generator 230 may generate the control bias VBIAS1 by performing voltage division of the first bias V1 and the second bias V2. The third bias generator 230 may include a third resistance string coupled between the node to which the first bias V1 is applied and the node to which the second bias V2 is applied.

In order to control the slope of the control bias VBIAS1 to the input bias VBIAS0, the first and second bias generators 210 and 220 receive the slope control signals CU1-CU6 and CD1-CD6 as inputs, respectively, and change the level of the first bias V1 and the second bias V2. Since the third bias generator 230 generates the control bias VBIAS1 using the first bias V1 and the second bias V2, the control bias VBIAS1 changes whenever the first bias V1 and the second bias V2 change.

Equations (1) through (3) indicate an exemplary operation of the control bias generating circuit in more detail. Variables R1, R2, R3 and R4 in equations (1) through (3) are defined as follows. R1 is the sum of resistances arranged in an upper region (e.g., RU1+RU2) when the slope control signal (e.g., CU3) is activated. R2 is the sum of resistances arranged in a lower region (e.g., RU3+RU4+RU5+RU6) when the slope control signal (e.g., CU3) is activated. R3 is the sum of resistances arranged in an upper region (e.g., RD1+RD2+RD3) when the slope control signal (e.g., CD3) is activated. R4 is the sum of resistances arranged in a lower region (e.g., RD4+RD5+RD6+RD7) when the slope control signal (e.g., CD3) is activated. Also, it is assumed that the two resistors in the third bias generator 230 have the same resistance values. With the definitions above, V1, V2 and VBIAS1 can be defined by Equation 1, Equation 2 and Equation 3, respectively.

$$\begin{matrix}V 1 = \frac{R 1}{R 1 + R 2} VBIAS 0 + \frac{R 2}{R 1 + R 2} VPP & ( 1 ) \\ V 2 = \frac{R 4}{R 3 + R 4} VBIAS 0 & ( 2 ) \\ VBIAS 1 = \frac{1}{2} ( \frac{R 1}{R 1 + R 2} + \frac{R 4}{R 3 + R 4} ) VBIAS 0 + \frac{1}{2} \frac{R 2}{R 1 + R 2} VPP & ( 3 )\end{matrix}$$

Referring to Equation 3, the slope of the control bias VBIAS1 to the input bias VBIAS0 can be controlled by changing the activated slope control signals CU1-CU6 and CD1-CD6, which change R1, R2, R3 and R4. Note that when the values of R1 and R2 change, the y-intercept of the line also changes.

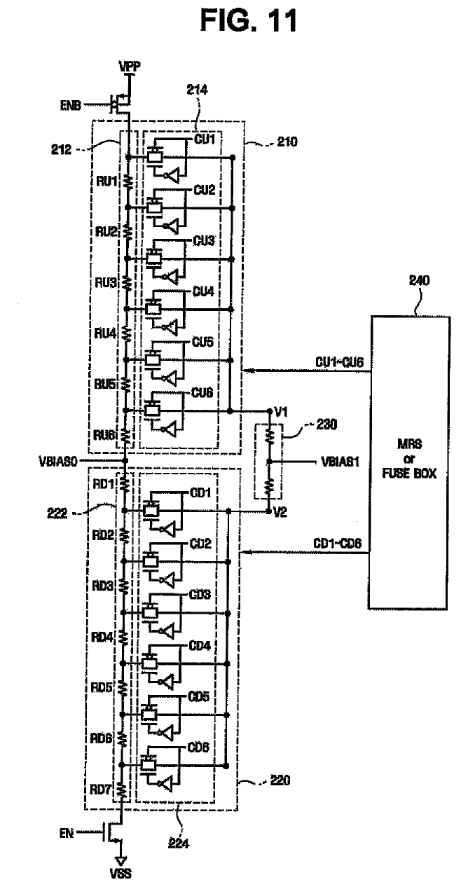

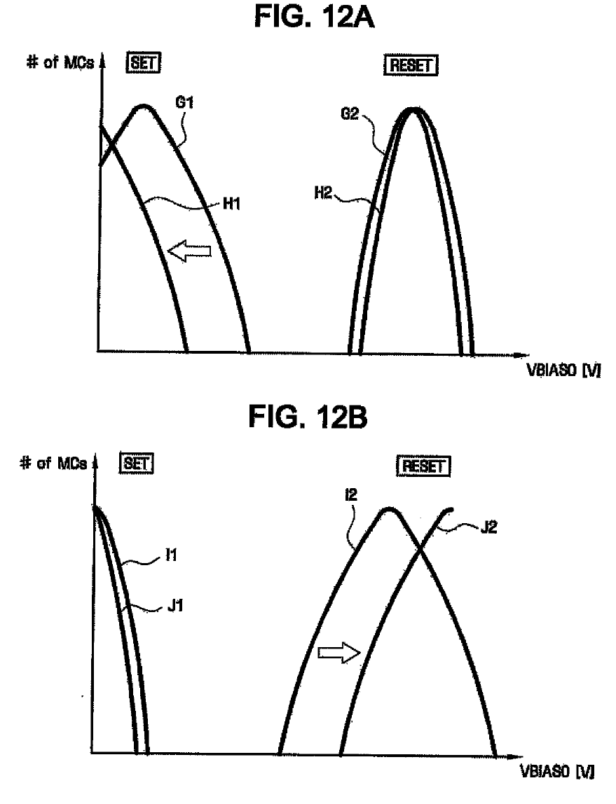

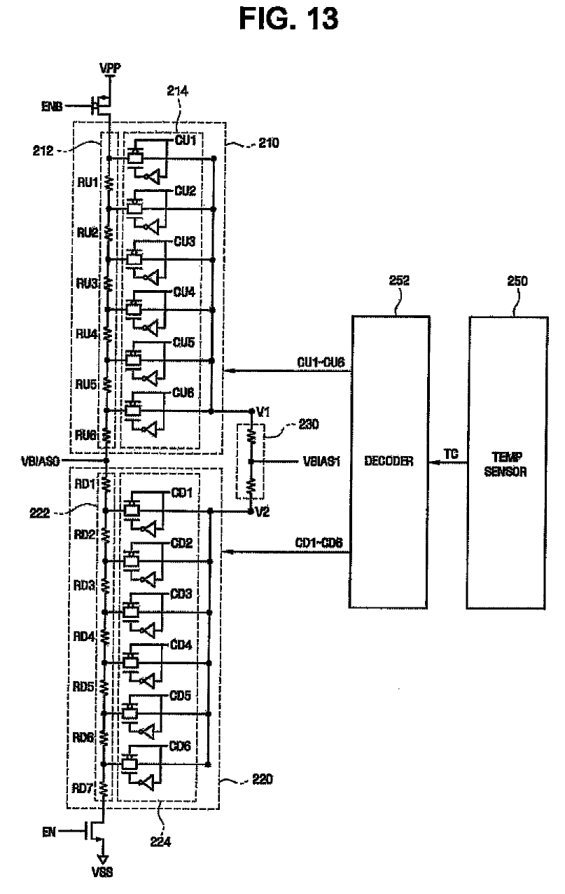

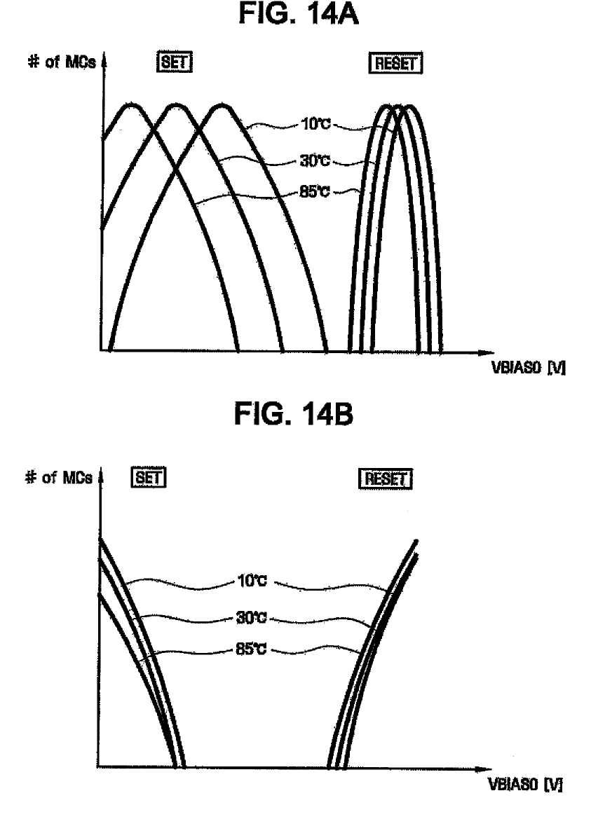

In order to minimize the impact of process condition changes in the fabrication process of the nonvolatile memory devices on the read operation, the slope of the control bias VBIAS1 to the input bias VBIAS0 can be adjusted by changing the first bias V1 and the second bias V2. More details are provided below, referring to FIGS. 11, 12A, and 12B. Also, in order to minimize the impact of temperature changes around the nonvolatile memory devices on the read operation, the slope of the control bias VBIAS1 to the input bias VBIAS0 can be adjusted by changing the first bias V1 and the second bias V2. More details are provided below, referring to FIGS. 13, 14A, and 14B.

FIGS. 11, 12A and 12B illustrate operation of the control bias generating circuit shown in FIG. 1, according to an exemplary embodiment of the present invention.

Referring to FIG. 11, which is a circuit diagram illustrating the control bias generating circuit, the slope control signals CU1-CU6 and CD1-CD6 can be MRS (Mode Register Set) signals or fuse box signals provided by MRS or fuse box 240, respectively. More specifically, multiple chips are fabricated in a single wafer and the characteristics of each chip may vary depending on the position on the wafer. For example, for a chip located in a corner of the wafer, the threshold voltage of the PMOS may be higher than the predetermined value and the threshold voltage of the NMOS may be lower than the predetermined value. In this case, the slope of the control bias VBIAS1 to the input bias VBIAS0 can be adjusted by controlling the level of the first bias V1 using the slope control signals CU1-CU6. For example, the slope control signals CU1-CU6 can be varied by cutting fuses in the fuse box 240.

Referring to FIG. 12A, reference labels G1 and G2 are curves representing the fabricated resistance distribution of the set data and the fabricated resistance distribution of the reset data, respectively, where the threshold voltage of the PMOS is higher than the predetermined value and the threshold voltage of the NMOS is lower than the predetermined value. Reference labels H1 an H2 are curves representing the resistance distribution of the set data and the resistance distribution of the reset data, respectively, after adjustment of the slope of the control bias VBIAS1 to the input bias VBIAS0. As H1 shifted to the left compared to G1, the sensing margin is improved.

Also, for a chip located in another corner of the wafer, the threshold voltage of the PMOS may be lower than the predetermined value and the threshold voltage of the NMOS may be higher than the predetermined value. In this case, the slope of the control bias VBIAS1 to the input bias VBIAS0 can be adjusted by controlling the level of the second bias V2 using the slope control signals CD1-CD6.

Referring to FIG. 12B, reference labels I1 and I2 are curves representing the fabricated resistance distribution of the set data and the fabricated resistance distribution of the reset data, respectively, where the threshold voltage of the PMOS is lower than the predetermined value and the threshold voltage of the NMOS is higher than the predetermined value. Reference labels J1 and J2 are curves representing the resistance distribution of the set data and the resistance distribution of the reset data, respectively, after adjustment of the slope of the control bias VBIAS1 to the input bias VBIAS0. As J2 shifted to the right compared to I2, the sensing margin is improved.

FIGS. 13, 14A, and 14B illustrate another operation of the control bias generating circuit shown in FIG. 1, according to an exemplary embodiment of the present invention.

Referring to FIG. 13, which is a circuit diagram illustrating the control bias generating circuit, a temperature sensor 250 outputs a temperature code TC in response to sensing ambient temperature. A decoder 252 provides the first bias generator 210 and the second bias generator 220 with the slope control signals CU1-CU6 and CD1-CD6 by decoding the temperature code TC.

Examples of temperature codes TC are shown below, in which 3 bits are used to represent each temperature code TC. Alternatively, 2 bits, 4 bits, etc., may be used to represent the temperature code TC in various embodiments.

TABLE 1

| | Temperature | | | | | | | |
|---|---|---|---|---|---|---|---|---|
| | −10° C. | 0° C. | 10° C. | 20° C. | 30° C. | 40° C. | 50° C. | 60° C. |
| Temp. Code TC | 000 | 001 | 010 | 011 | 100 | 101 | 110 | 111 |

More specifically, when the ambient temperature changes, the resistance of the phase change material also changes. For example, the resistance of the set data can be 6 kΩ and 3.45 kΩ at temperatures of 25° C. and 85° C., respectively. Also, the resistance of the reset data can be 150 kΩ and 50 kΩ at temperatures of 25° C. and 85° C., respectively. Therefore, as illustrated in FIG. 14A, the resistance distribution of the set data and the resistance distribution of the reset data show significant differences at the temperatures of 10° C., 30° C. and 85° C.

The slope of the control bias VBIAS1 to the input VBIAS0 can be adjusted by operations of the temperature sensor 250 and the decoder 252. The temperature sensor 250 senses ambient temperature and ouputs temperature code TC, and the decoder 252 decodes temperature code TC to change control signals CU1-CU6 and CD1-CD6. Accordingly, the resistance distribution of the set data and the resistance distribution of the reset data are not affected by the temperature, as shown in FIG. 14B, and thus the sensing margin of the input bias VBIAS0 is increased.

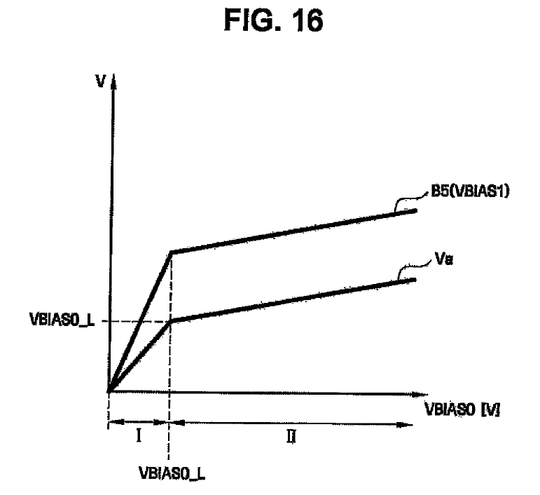

FIG. 15 is a block diagram illustrating a control bias generating circuit, shown in FIG. 1, according to another exemplary embodiment of the present invention. FIG. 16 is a graph illustrating operation of the block diagram shown in FIG. 15. FIG. 15 is an exemplary control bias generating circuit that implements the operations described with reference to FIG. 7, although the present embodiment is not limited to this implementation.

Referring to FIGS. 15 and 16, the control bias generating circuit may include a detecting unit 270 and an amplification unit 280.

The detecting unit 270 outputs the input bias VBIAS0 without any modification when the input bias VBIAS0 is in a first region I. When the input bias VBIAS0 is in a second region II, the detecting unit 270 clamps the input bias VBIAS0 to the level of the first level VBIAS0_L, or close to the level of the first level VBIAS0_L. Therefore, as shown in FIG. 16, in the first region I, the slope of an output signal Va of the detecting unit 270 to the input bias VBIAS0 is 1, and in the second region II, the slope of the output signal Va of the detecting unit 270 to the input bias VBIAS0 becomes less than 1 (e.g., close to 0).

The amplification unit 280 outputs the control bias VBIAS1 by amplifying the output signal Va of the detecting unit 270 in a predetermined proportion. Thus, as shown in FIG. 16, although the slope of the control bias VBIAS1 to the input bias VBIAS0 is greater than 1 in the first region I, the slope of the control bias VBIAS1 to the input bias VBIAS0 can be less than 1 in the second region II.

The amplification unit 280 can include an operational amplifier OP amp 282, a PMOS transistor MP4, and resistors Ra and Rb. The OP amp 282 has a (−) input node connected to the output signal Va of the detecting unit 270 and a (+) input node having a feedback loop. Also, the operation voltage VPP is applied to the OP amp 282, and the level of the operation voltage VPP can be the source voltage or the boosting voltage. The PMOS transistor MP4, controlled by the output signal of the OP amp 282, provides the control bias VBIAS1 through an output node NOUT.

The resistors Ra and Rb are coupled in series between the output node NOUT and a ground voltage node VSS, and determine the slope of the control bias VBIAS1 to the input bias VBIAS0. As a result, the slope of the control bias VBIAS1 to the input bias VBIAS0 can be adjusted based on different ratios of the resistances Ra and Rb. The amplification unit 280 amplifies the output signal Va of the detecting unit 270 at a ratio of (1+Rb/Ra). Therefore, the control bias VBIAS1 is equal to (1+Rb/Ra)×Va.

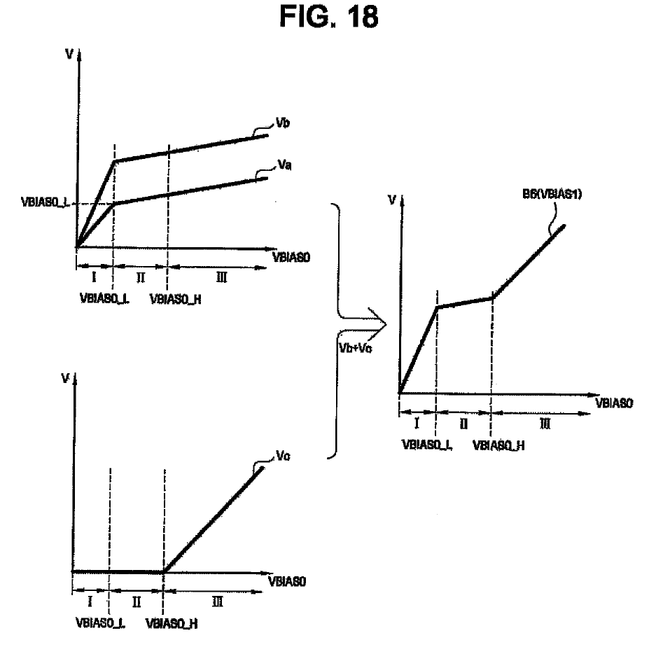

FIG. 17 is a block diagram illustrating a control bias generating circuit, shown in FIG. 1, according to another exemplary embodiment of the present invention. FIG. 18 is a graph illustrating operation of the block diagram shown in FIG. 17. FIG. 17 is an exemplary control bias generating circuit that implements the operations described with reference to FIG. 8, although the present embodiment is not limited to this implementation.

Referring to FIGS. 17 and 18, a control bias generating circuit 200 includes a detecting unit 270, an amplification unit 280, as well as a compensation unit 290.

The compensation unit 290 increases the level of the control bias VBAIS1 when the input bias VBIAS0 is in a third region III. More specifically, the compensation unit 290 does not operate in a region where an input bias VBIAS0 is less than a second level VBIAS0_H (i.e., in the first region I and the second region II). The compensation unit 290 operates only in a region where the input bias VBIAS0 is greater than the input bias VBIAS0H (i.e., the third region III) and provides an output signal Vc through an output node NOUT.

Therefore, as illustrated in FIG. 18, in the first region I and the second region II, the slope of the output signal Vc of the compensation unit 290 to the input bias VBIAS0 is 0. In the third region III, the slope of the output signal Vc of the compensation unit 290 to the input bias VBIAS0 is a positive value. As a result, the control bias VBIAS1, which is the sum of an output signal Vb of the amplification unit 280 and the output signal Vc of the compensation unit 290, is generated. Therefore, the slope of the control bias VBIAS1 to the input bias VBIAS0 in the second region II may be less than the slope of the control bias VBIAS1 to the input bias VBIAS0 in the first region I and the third region III. Specially, the slope of the control bias VBIAS1 to the input bias VBIAS0 in the second region II can be less than 1.

The compensation unit 290 includes an OP amp 292 and a PMOS transistor MP5. A (−) input node of the OP amp 292 receives the input bias VBIAS0 as an input, and a (+) input node receives a fixed bias of the second level VBIAS0_H as an input. The OP amp 292 generates output by amplifying the level difference between the input bias VBIAS0 and the fixed bias of the second level VBIAS0_H.

The PMOS transistor MP5 is designed to have a threshold voltage such that it only operates in the region where the input bias VBIAS0 is greater than the second bias VBIAS0_H. In other words, the PMOS transistor MP5 does not operate in the region where the input bias VBIAS0 is less than the second level VBIAS0_H. For example, the PMOS transistor MP5 can be designed to have a threshold voltage, so that it will not turn on when the output of the OP amp 292 is a positive voltage.

As described above, a nonvolatile memory device has a large sensing margin by adjusting a slope of a control bias to an input bias. As a result, the reliability of the read operation can be improved. Thus, the illustrative embodiments provide a nonvolatile memory device with a more reliable read operation.

While the present invention has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A nonvolatile memory device comprising:
a nonvolatile memory cell having a resistance level that changes depending on stored data;
a read circuit that reads the resistance level of the nonvolatile memory cell by receiving a control bias and supplying the nonvolatile memory cell a read bias based on the control bias; and
a control bias generating circuit that receives an input bias, generates the control bias based on the input bias and supplies the control bias to the read circuit,
wherein a slope of the control bias to the input bias is less than 1.

2. The nonvolatile memory device of claim 1, wherein the control bias generating circuit controls the slope of the control bias to the input bias based on a slope control signal.

3. The nonvolatile memory device of claim 2, wherein the slope control signal comprises one of a temperature signal, an MRS (Mode Register Set) signal, or a fuse box signal.

4. The nonvolatile memory device of claim 1, wherein the control bias generating circuit comprises:
a first bias generator that generates a first bias having a level is higher than a level of the input bias;
a second bias generator that generates a second bias having a level is lower than the level of the input bias; and
a third bias generator that generates the control bias based on the first bias and the second bias.

5. The nonvolatile memory device of claim 4, wherein the first bias generator receives a first slope control signal and changes the level of the first bias in accordance with the first slope control signal, and the second bias generator receives a second slope control signal and changes the level of the second bias in accordance with the second slope control signal.

6. The nonvolatile memory device of claim 4, wherein the first bias generator and the second bias generator change the levels of the first bias and the second bias, respectively, depending on an ambient temperature.

7. The nonvolatile memory device of claim 4, wherein the first bias generator and the second bias generator change the levels of the first bias and the second bias, respectively, depending on a change of a threshold voltage of a MOS transistor.

8. The nonvolatile memory device of claim 4, wherein the first bias generator comprises a first resistance string coupled between an operation voltage node and an input bias node, and a first selection circuit that responds a first slope control signal to output one node voltage as the first bias among node voltages on the first resistance string, and
wherein the second bias generator comprises a second resistance string coupled between the input bias node and a ground voltage node, and a second selection circuit that responds to a second slope control signal to output one node voltage as the second bias among node voltages on the second resistance string.

9. The nonvolatile memory device of claim 8, wherein the third bias generator comprises a third resistance string coupled between a first node to which the first bias is applied and a second node to which the second bias is applied.

10. The nonvolatile memory device of claim 1, wherein slopes of the control bias to the input bias are different in a plurality of regions depending on the input bias level, and the slope of the control bias to the input bias is less than one in at least one region of the plurality regions.

11. The nonvolatile memory device of claim 10, wherein the plurality of regions comprises a first region in which the input bias is less than a first level and a second region in which the input bias is greater than the first level, the slope of the control bias to the input bias in the second region being less than the slope of the control bias to the input bias in the first region, and the slope of the control bias to the input bias in the second region being less than 1.

12. The nonvolatile memory device of claim 11, wherein data stored in the nonvolatile memory cell is set data or reset data, and the first level is the same as or greater than a bias level corresponding to the maximum resistance level of the set data.

13. The nonvolatile memory device of claim 10, wherein the plurality of regions comprises a first region in which the input bias is less than a first level, a second region in which the input bias is greater than the first level and less than a second level, and a third region in which the input bias is greater than the second level, the slope of the control bias to the input bias in the second region being less than the slopes of the control bias to the input bias in the first region and in the third region, and the slope of the control bias to the input bias in the second region being less than 1.

14. The nonvolatile memory device of claim 13, wherein data stored in the nonvolatile memory cell is set data or reset data, the first level is the same as or greater than a bias level corresponding to the maximum resistance level of the set data, and the second level is the same as or less than a bias level corresponding to the minimum resistance level of the reset data.

15. The nonvolatile memory device of claim 10, wherein the plurality of the regions comprises a first region where the input bias is less than a first level and a second region where the input bias is greater than the first level, and
wherein the control bias generating circuit comprises a detecting unit, which outputs a constant bias of the input bias when the input bias is in the first region and clamps the input bias to the first level or to about the first level when the input bias is in the second region, and an amplification unit, which amplifies an output signal of the detecting unit and outputs the control bias.

16. The nonvolatile memory device of claim 15, wherein the plurality of regions comprises a first region where the input bias is less than a first level, a second region where input bias is greater than the first level and less than a second level, and a third region where input bias is greater than the second level, and
wherein the control bias generating circuit further comprises a compensation unit, which increases the level of the control bias when the input bias is in the third region.

17. The nonvolatile memory device of claim 1, wherein the read circuit comprises:
a clamping circuit coupled between a bit line, coupled to a selected nonvolatile memory cell, and a sensing node, the clamping circuit clamping the bit line to a predetermined bias level;
a precharge circuit that precharges the sensing node;
a read bias generating circuit that generates the read bias for the sensing node based on the control bias; and
a sense amplifier circuit that compares a level of the sensing node and a reference level, and outputs a comparison output.

18. A nonvolatile memory device comprising:
a nonvolatile memory cell having a resistance level that changes depending on stored data;
a read circuit that reads the resistance level of the nonvolatile memory cell by receiving a control bias and supplying the nonvolatile memory cell a read bias based on the control bias; and
a control bias generating circuit that receives an input bias, generates the control bias based on the input bias, supplies the control bias to the read circuit, and controls a slope of the control bias to the input bias depending on a slope control signal.

19. The nonvolatile memory device of claim 18, wherein the slope control signal comprises one of a temperature signal, an MRS (Mode Register Set) signal, or a fuse box signal.

20. The nonvolatile memory device of claim 18, wherein a slope of the control bias to the input bias is less than 1.

21. A nonvolatile memory device comprising:
a nonvolatile memory cell which has a resistance level that is changeable depending on stored data;
a read circuit that reads the resistance level of the nonvolatile memory cell by receiving a control bias and supplying the nonvolatile memory cell a read bias based on the control bias; and
a control bias generating circuit that receives an input bias, generates the control bias based on the input bias and supplies the control bias to the read circuit, a slope of the control bias to the input bias being different in a plurality of regions depending on a level of the input bias.

22. The nonvolatile memory device of claim 21, wherein the slope of the control bias to the input bias is less than 1 in at least one region among the plurality of the regions.

23. The nonvolatile memory device of claim 21, wherein the plurality of regions comprises a first region in which the input bias is less than a first level and a second region in which the input bias is greater than the first level, and
wherein the slope of the control bias to the input bias in the second region is less than the slope of the control bias to the input bias in the first region.

24. The nonvolatile memory device of claim 21, wherein the plurality of the regions comprises a first region in which the input bias is less than a first level, a second region in which the input bias is greater than the first level and less than a second level, and a third region in which the input bias is greater than the second level, and
wherein a slope of the control bias to the input bias in the second region is less than the slopes of the control bias to the input bias in the first region and the third region.

25. A nonvolatile memory device comprising:
a first bias generator that receives an input bias and generates a first bias having a level higher than the input bias;
a second bias generator that receives the input bias and generates a second bias having a level lower than the input bias; and
a third bias generator that generates a third bias using the first bias and the second bias, wherein a slope of the third bias to the input bias is less than 1.

26. The nonvolatile memory device of claim 25, wherein the first bias generator receives a first slope control signal and changes the level of the first bias in response to the first slope control signal, and the second bias generator receives a second slope control signal and changes the level of the second bias in response to the second slope control signal.

27. The nonvolatile memory device of claim 25, wherein the first bias generator comprises a first resistance string coupled between an operation voltage node and an input bias node, and a first selection circuit that responds to a first slope control signal to output one node voltage as the first bias among the node voltages on the first resistance string, and
wherein the second bias generator comprises a second resistance string coupled between the input bias node and a ground voltage node, and a second selection circuit that responds to a second slope control signal to output one node voltage as the second bias among the node voltages of the second resistance string.

28. The nonvolatile memory device of claim 27, wherein the third bias generator comprises a third resistance string coupled between a first node to which the first bias is applied and a second node to which the second bias is applied.
